(19) United States
(12) Patent Application Publication
(10) Pub. No.: US 2024/0155780 A1
(43) Pub. Date: May 9, 2024

(54) ELECTRONIC DEVICE

(71) Applicant: PANASONIC INTELLECTUAL PROPERTY MANAGEMENT CO., LTD., Osaka (JP)

(72) Inventor: Hajime OHTAKI, Kanagawa (JP)

(73) Assignee: PANASONIC INTELLECTUAL PROPERTY MANAGEMENT CO., LTD., Osaka (JP)

(21) Appl. No.: 18/386,169

(22) Filed: Nov. 1, 2023

(30) Foreign Application Priority Data
Nov. 4, 2022 (JP) 2022-177247

(51) Int. Cl. H05K 5/00

(52) U.S. Cl. CPC H05K 5/006; H05K 5/0008

(57) ABSTRACT

An electronic device has a case body including at least a bottom surface, first, second, third, and fourth upright wall portions disposed around the bottom surface, a circuit board accommodated in the case body, and a lid portion disposed so as to correspond to at least a part of first, second, third, and fourth top portions of the first, second, third, and fourth upright wall portions, covering the circuit board, and having inner and outer surfaces. The lid portion includes a contact portion provided on a part of the inner surface, and a continuous protruding portion continuous with a predetermined length and protruding toward the bottom surface. When the electronic device is disposed with the first upright wall portion downward, at least one of long sides of the continuous protruding portion on the inner surface is disposed above the contact portion so as to cover the contact portion.

### CROSS-REFERENCE TO RELATED APPLICATIONS

This application is based on and claims priority under 35 USC 119 from Japanese Patent Application No. 2022-177247 filed on Nov. 4, 2022, the entire content of which is incorporated herein by reference.

### TECHNICAL FIELD

The present disclosure relates to an electronic device.

### BACKGROUND ART

An electronic control unit (ECU) is mounted on a vehicle. When a water droplet adheres to a circuit board of the ECU, there is a concern that an operation of the ECU may be hindered. Patent Literature 1 discloses a case body for accommodating ECU configured such that, in a case where a water droplet drips on an upper surface of the case body separated from an opening portion, when the water droplet moves toward a connector mounting surface side on the upper surface due to vibration of a vehicle during traveling, or when the water droplet moves toward the connector mounting surface side on the upper surface during acceleration of the vehicle, the water droplet is guided by a step portion to both sides of the opening on the upper surface, then guided downward along left and right side surfaces of the case body, and drips from a portion of a lower surface of the case body separated from the opening portion.

### CITATION LIST

### Patent Literature

Patent Literature 1: JP2020-161624A

### SUMMARY OF INVENTION

However, although the configuration disclosed in Patent Literature 1 can prevent the water droplet moving toward the connector mounting surface from entering through the opening portion, the configuration cannot prevent the water droplet entering through a gap between the case body from adhering to the circuit board.

An object of the present disclosure is to provide a technique for preventing a water droplet entering from a gap of an electronic device from adhering to a circuit board.

An electronic device according to the present disclosure includes at least a bottom surface, a first upright wall portion, a second upright wall portion, a third upright wall portion, and a fourth upright wall portion disposed around the bottom surface; a circuit board on which an electronic component is mounted and which is accommodated in the case body; and a lid portion disposed so as to correspond to at least a part of a first top portion of the first upright wall portion, a second top portion of the second upright wall portion, a third top portion of the third upright wall portion, and a fourth top portion of the fourth upright wall portion, covering the circuit board, and having an inner surface facing the bottom surface and an outer surface opposite to the inner surface. The lid portion includes a contact portion provided on a part of the inner surface and configured to be in contact with the circuit board. The lid portion includes a continuous protruding portion that is continuous with a predetermined length along the inner surface and protrudes toward the bottom surface. In a case where the electronic device is disposed with the first upright wall portion downward, at least one of long sides of the continuous protruding portion on the inner surface is disposed above the contact portion so as to cover the contact portion.

According to the present disclosure, it is possible to prevent the water droplet entering from the gap of the electronic device from adhering to the circuit board.

### BRIEF DESCRIPTION OF DRAWINGS

FIG. 1 is a diagram illustrating an example in which an electronic device according to an embodiment is mounted on a vehicle;

FIG. 2 is a perspective view illustrating an example of the electronic device according to the present embodiment as viewed from a case body side;

FIG. 3 is a perspective view illustrating the example of the electronic device according to the present embodiment, as viewed from a circuit board side, with a case body removed;

FIG. 4 is a perspective view illustrating the example of the electronic device according to the present embodiment as viewed from a lid portion side;

FIG. 5 is a perspective view illustrating an example of a case where an inner surface of the lid portion is viewed with a first upright wall portion according to the present embodiment downward;

FIG. 6 is a perspective view illustrating an example of a case where the inner surface of the lid portion is viewed with a third upright wall portion according to the present embodiment downward; and

FIG. 7 is a perspective view illustrating an example of a case where the inner surface of the lid portion is viewed with a fourth upright wall portion according to the present embodiment downward.

### DESCRIPTION OF EMBODIMENTS

Hereinafter, an embodiment of the present disclosure will be described in detail with reference to the drawings as appropriate. However, more detailed description may be omitted. For example, detailed description of already well-known matters and redundant description of substantially the same configuration may be omitted. This is to avoid the following description from being unnecessarily redundant and facilitate understanding by those skilled in the art. It should be noted that the accompanying drawings and the following description are provided for a person skilled in the art to sufficiently understand the present disclosure, and are not intended to limit the subject matter described in claims.

### Embodiment

### <Configuration of Vehicle>

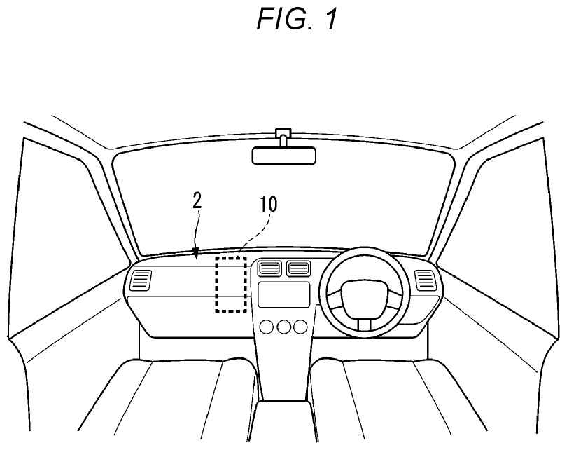

FIG. 1 is a diagram illustrating an example in which an electronic device 10 according to the present embodiment is mounted on a vehicle.

Various electronic devices represented by ECUs are mounted on a vehicle. For example, the electronic device may be mounted outside a vehicle compartment such as an engine room, or may be mounted in an instrument panel 2 or a console box in the vehicle compartment as illustrated in FIG. 1.

Although an electronic device mounted outside the vehicle compartment has a complete waterproof structure, an electronic device mounted inside the vehicle compartment generally does not have a complete waterproof structure due to a reduction in the number of components, a reduction in cost, or the like. However, even in the vehicle compartment, a water droplet may be generated, for example, when a windshield is washed with water from the inside, when drinking water is erroneously spilled, or when condensation occurs in a duct of an air conditioner. When such water droplet reach a circuit board in the electronic device mounted in the vehicle compartment, there is a concern that the water droplet may interfere with an operation of the electronic device.

In the present embodiment, a structure of the electronic device 10 that prevents a water droplet generated and dropped in the vehicle compartment from reaching the circuit board in the electronic device (that is, the electronic device 10 has a drip-proof performance) will be described. However, the structure of the electronic device 10 according to the present embodiment is not limited to being applied to an electronic device mounted on a vehicle. For example, the structure of the electronic device 10 according to the present embodiment is also applicable to the electronic device 10 mounted on a railway vehicle, an aircraft, an agricultural machine, a construction machine, a personal computer, a printer, a smartphone, or the like.

<Structure of Electronic Device>

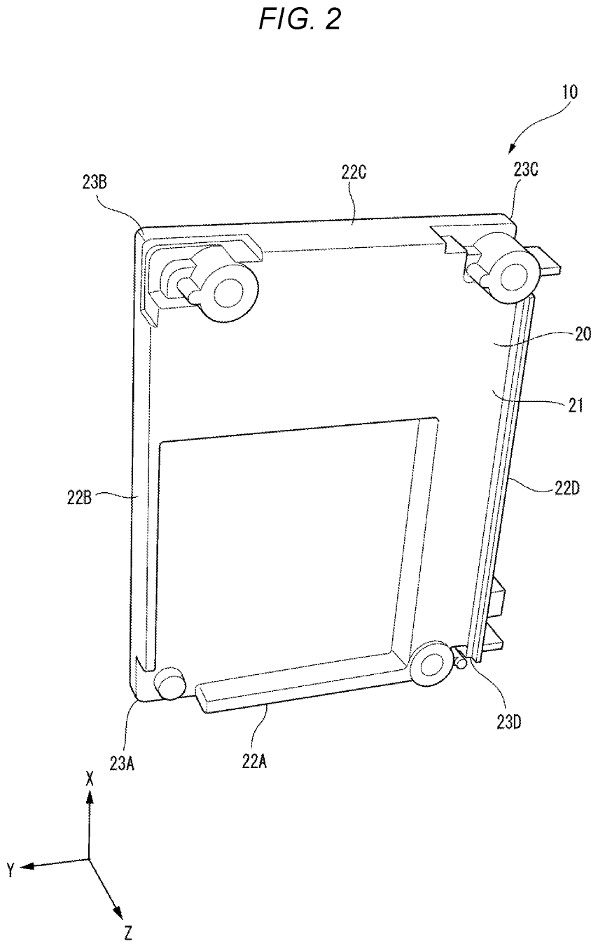

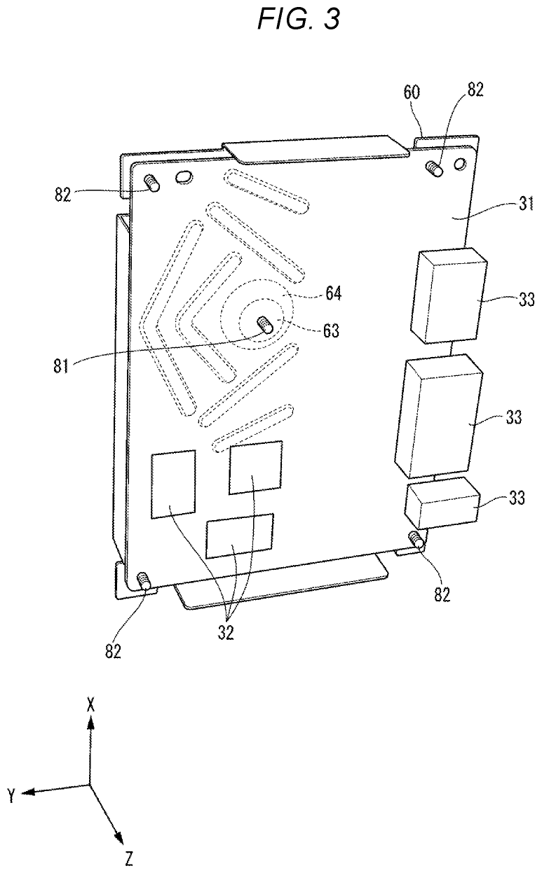

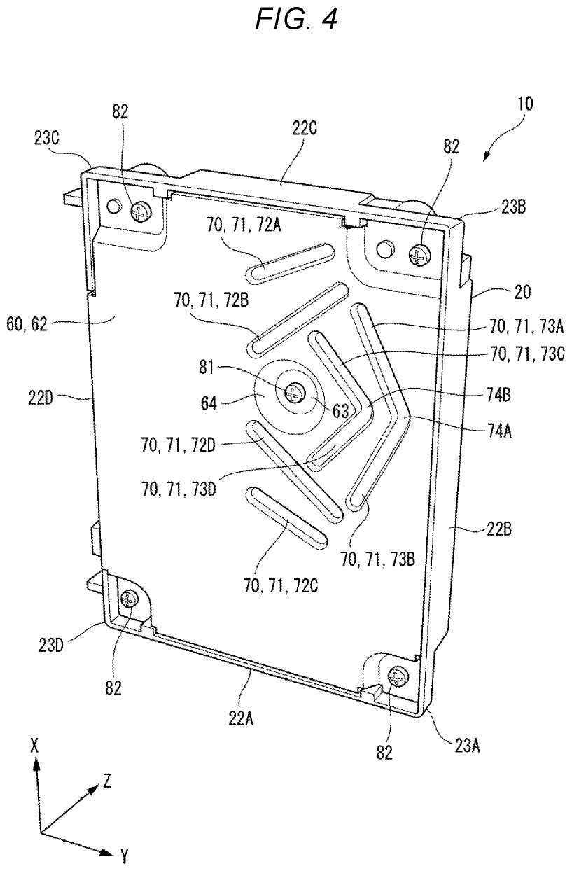

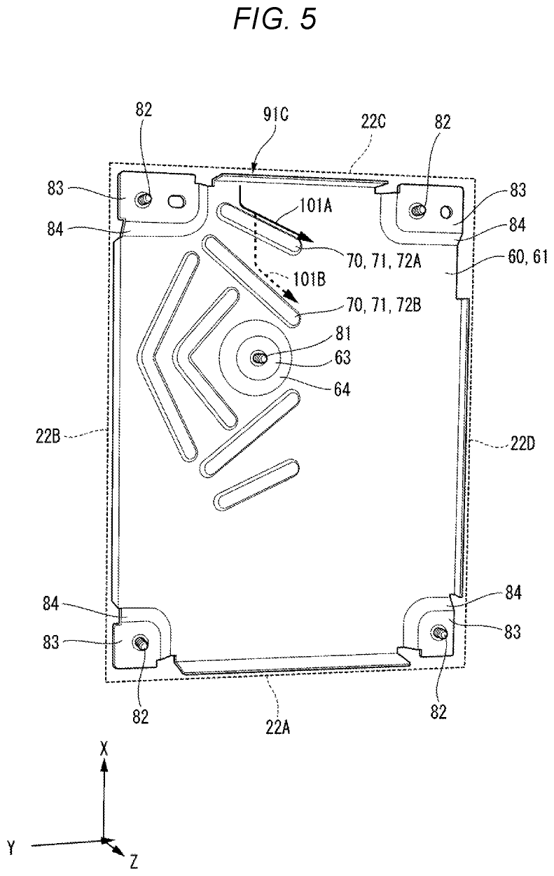

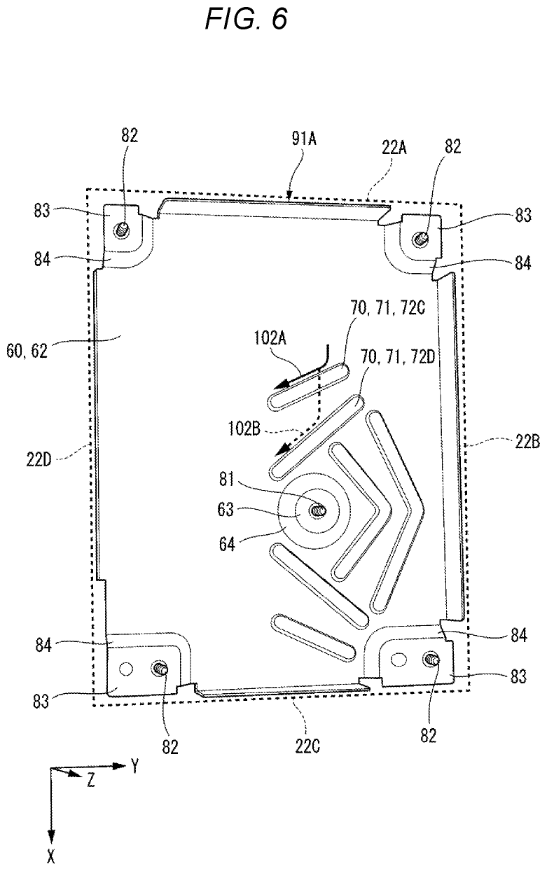

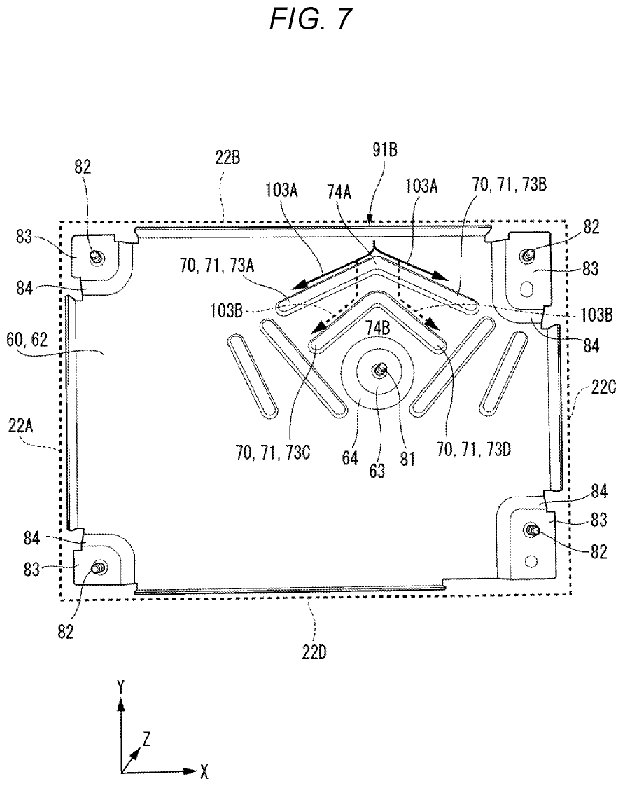

FIG. 2 is a perspective view illustrating an example of the electronic device 10 according to the present embodiment as viewed from a case body 20. FIG. 3 is a perspective view illustrating the example of the electronic device 10 according to the present embodiment, as viewed from a circuit board 31 side, with the case body 20 removed. FIG. 4 is a perspective view illustrating the example of the electronic device 10 according to the present embodiment as viewed from a lid portion 60 side. FIG. 5 is a perspective view illustrating an example of a case where an inner surface 61 of the lid portion 60 is viewed with a first upright wall portion 22A according to the present embodiment downward. FIG. 6 is a perspective view illustrating an example of a case where the inner surface 61 of the lid portion 60 is viewed with a third upright wall portion 22C according to the present embodiment downward. FIG. 7 is a perspective view illustrating an example of a case where the inner surface 61 of the lid portion 60 is viewed with a fourth upright wall portion 22D according to the present embodiment downward.

For convenience of description, as illustrated in FIGS. 2 to 7, an axis extending from the first upright wall portion 22A to the third upright wall portion 22C is defined as an X-axis. An axis extending from the fourth upright wall portion 22D to a second upright wall portion 22B and perpendicular to the X-axis is defined as a Y-axis. An axis extending from the lid portion 60 to a bottom surface 21 of the case body 20 and perpendicular to the X-axis and the Y-axis is defined as a Z-axis. Note that the definition of the axis is used for convenience of description, and is not intended to limit a posture of the structure at the time of actual use.

The electronic device 10 includes the case body 20, the circuit board 31, and the lid portion 60. As illustrated in FIGS. 2 and 4, the electronic device 10 may have a substantially rectangular parallelepiped shape.

The case body 20 includes at least the bottom surface 21, and the first upright wall portion 22A, the second upright wall portion 22B, the third upright wall portion 22C, and the fourth upright wall portion 22D disposed around the bottom surface 21. The bottom surface 21 may have a substantially rectangular shape. The first upright wall portion 22A, the second upright wall portion 22B, the third upright wall portion 22C, and the fourth upright wall portion 22D may be wall surfaces that are respectively positioned on four sides of the bottom surface 21, are perpendicular to the bottom surface 21, and extend toward the lid portion 60 (that is, in a Z-axis direction). In the present embodiment, the first upright wall portion 22A and the third upright wall portion 22C are disposed to face each other, and the second upright wall portion 22B and the fourth upright wall portion 22D are disposed to face each other.

As illustrated in FIG. 3, electronic components 32 are mounted on the circuit board 31, and the circuit board 31 is accommodated in the case body 20. Examples of the electronic component 32 include a large scale integrated circuit (LSI), a central processing unit (CPU), a controller, and a memory.

As illustrated in FIG. 3, connectors 33 for connecting the circuit board 31 to external devices, power supplies, or the like may be disposed on the fourth upright wall portion 22D side of the circuit board 31.

The lid portion 60 is disposed to correspond to at least a part of a first top portion 23A of the first upright wall portion 22A, a second top portion 23B of the second upright wall portion 22B, a third top portion 23C of the third upright wall portion 22C, and a fourth top portion 23D of the fourth upright wall portion 22D, and covers the circuit board 31. For example, the lid portion 60 may have a rectangular shape. The first top portion 23A, the second top portion 23B, the third top portion 23C, and the fourth top portion 23D may be top end surfaces of the first upright wall portion 22A, the second upright wall portion 22B, the third upright wall portion 22C, and the fourth upright wall portion 22D, and are not limited to the top end surfaces and may include side surfaces near the top end surfaces, respectively. In addition, the lid portion 60 may be disposed slightly away from at least a part of the first top portion 23A, the second top portion 23B, the third top portion 23C, and the fourth top portion 23D.

For example, as illustrated in FIG. 3, the circuit board 31 is disposed along the bottom surface 21 of the case body 20, and is accommodated in a space formed by the bottom surface 21, the first upright wall portion 22A, the second upright wall portion 22B, the third upright wall portion 22C, and the fourth upright wall portion 22D of the case body 20, and the lid portion 60.

The lid portion 60 has the inner surface 61 facing the bottom surface 21 of the case body 20 and an outer surface 62 opposite to the inner surface 61. The lid portion 60 includes a contact portion 63 provided on a part of the inner surface 61 and configured to be in contact with the circuit board 31.

The lid portion 60 includes a protruding portion 64 corresponding to the contact portion 63. The protruding portion 64 may protrude toward the bottom surface 21 of the case body 20. The lid portion 60 and the circuit board 31 are fastened by, for example, a screw 81 at the contact portion 63. By providing the protruding portion 64, a predetermined gap is formed between the circuit board 31 and the inner surface 61 of the lid portion 60. The lid portion 60, the circuit board 31, and the case body 20 may be fastened at four corners by, for example, screws 82.

The lid portion 60 includes continuous protruding portions 70 that are continuous with a predetermined length along the inner surface 61 and protrude toward the bottom surface 21. As described above, the gap is formed between the circuit board 31 and the inner surface 61 of the lid portion 60, and the continuous protruding portion 70 protrudes so as not to contact the circuit board 31.

The lid portion 60 may be made of metal (for example, sheet metal or aluminum die casting). The protruding portion 64 and the continuous protruding portion 70 may be formed on the lid portion 60 made of metal by press working. Accordingly, the continuous protruding portion 70 having any shape can be easily formed.

<<Case of Disposing Electronic Device 10 with First Upright Wall Portion 22A Downward>>

As illustrated in FIG. 5, in a case where the electronic device 10 is disposed in the vehicle compartment with the first upright wall portion 22A downward, a first long side 72A, which is at least one of long sides 71 of the continuous protruding portions 70 on the inner surface 61 of the lid portion 60, is disposed above the contact portion 63 so as to cover the contact portion 63.

A second long side 72B, which is at least one of the long sides 71 of the continuous protruding portions 70, may be disposed along the first long side 72A. For example, as illustrated in FIG. 5, the second long side 72B is disposed below the first long side 72A and above the contact portion 63 along the first long side 72A. As illustrated in FIG. 5, the first long side 72A and the second long side 72B may be disposed obliquely.

Accordingly, for example, as illustrated in FIG. 5, when the electronic device 10 is disposed with the first upright wall portion 22A downward, the first long side 72A and the second long side 72B are disposed above the contact portion 63 so as to cover the contact portion 63 and be inclined. Inclination angles of the first long side 72A and the second long side 72B may be the same (not illustrated) or may be different from each other (see FIG. 5). For example, as illustrated in FIG. 5, the inclination angle of the second long side 72B may be larger than the inclination angle of the first long side 72A. The first long side 72A and the second long side 72B may be inclined in a straight line (see FIG. 5) or may be inclined in a curved line (not illustrated). In addition, when the second long side 72B is positioned below the first long side 72A, the second long side 72B may be longer than the first long side 72A.

FIG. 5 illustrates an example in which the lid portion 60 has two long sides 71, that is, the first long side 72A and the second long side 72B, but the number of long sides 71 may be one, three or more.

Next, as illustrated in FIG. 5, operation and effects of the first long side 72A and the second long side 72B in the case where the electronic device 10 is disposed with the first upright wall portion 22A downward will be described.

For example, when a water droplet enters from a third gap 91C that is a gap between the third upright wall portion 22C and the lid portion 60, the water droplet moves downward along the inner surface 61 of the lid portion 60. However, the water droplet hits the first long side 72A and moves along the inclination of the first long side 72A (see a water droplet path 101A). Even if some of the water droplets that hits the first long side 72A moves downward without following the inclination of the first long side 72A, the water droplet hits the second long side 72B and moves along the inclination of the second long side 72B (see a water droplet path 101B).

As described above, by providing the first long side 72A and the second long side 72B on the inner surface 61 of the lid portion 60 as illustrated in FIG. 5, it is possible to prevent the water droplet entering from the third gap 91C from reaching the contact portion 63. That is, it is possible to prevent the water droplet entering from the third gap 91C from reaching the circuit board 31 through the contact portion 63.

<<Case of Disposing Electronic Device 10 with Third Upright Wall Portion 22C Downward>>

As illustrated in FIG. 6, in a case where the electronic device 10 is disposed in the vehicle compartment with the third upright wall portion 22C downward, a third long side 72C, which is at least one of the long sides 71 of the continuous protruding portions 70 on the inner surface 61 of the lid portion 60, is disposed above the contact portion 63 so as to cover the contact portion 63.

A fourth long side 72D, which is at least one of the long sides 71 of the continuous protruding portions 70, may be disposed along the third long side 72C. For example, as illustrated in FIG. 6, the fourth long side 72D is disposed below the third long side 72C and above the contact portion 63 along the third long side 72C. As illustrated in FIG. 6, the third long side 72C and the fourth long side 72D may be disposed obliquely.

Accordingly, for example, as illustrated in FIG. 6, in the case where the electronic device 10 is disposed with the third upright wall portion 22C downward, the third long side 72C and the fourth long side 72D are disposed above the contact portion 63 so as to cover the contact portion 63 and be inclined. Inclination angles of the third long side 72C and the fourth long side 72D may be the same (not illustrated) or may be different from each other (see FIG. 6). For example, as illustrated in FIG. 6, the inclination angle of the fourth long side 72D may be larger than the inclination angle of the third long side 72C. The third long side 72C and the fourth long side 72D may be inclined in a straight line (see FIG. 6) or may be inclined in a curved line (not illustrated). In addition, when the fourth long side 72D is positioned below the third long side 72C, the fourth long side 72D may be longer than the third long side 72C.

FIG. 6 illustrates an example in which the lid portion 60 has two long sides 71, that is, the third long side 72C and the fourth long side 72D, but the number of long sides 71 may be one, three or more.

Next, as illustrated in FIG. 6, operation and effects of the third long side 72C and the fourth long side 72D in the case where the electronic device 10 is disposed with the third upright wall portion 22C downward will be described.

For example, when a water droplet enters from a first gap 91A that is a gap between the first upright wall portion 22A and the lid portion 60, the water droplet moves downward along the inner surface 61 of the lid portion 60. However, the water droplet hits the third long side 72C and moves along the inclination of the third long side 72C (see a water droplet path 102A). Even if some of the water droplets that hits the third long side 72C moves downward without following the inclination of the third long side 72C, the water droplet hits the fourth long side 72D and moves along the inclination of the fourth long side 72D (see a water droplet path 102B).

As described above, by providing the third long side 72C and the fourth long side 72D on the inner surface 61 of the lid portion 60 as illustrated in FIG. 6, it is possible to prevent the water droplet entering from the first gap 91A from reaching the contact portion 63. That is, it is possible to prevent the water droplet entering from the third gap 91C from reaching the circuit board 31 through the contact portion 63.

<<Case of Disposing Electronic Device 10 with Fourth Upright Wall Portion 22D Downward>>

As illustrated in FIG. 7, in a case where the electronic device 10 is disposed in the vehicle compartment with the fourth upright wall portion 22D downward, at least one of the long sides 71 of the continuous protruding portions 70 on the inner surface 61 of the lid portion 60 may include a first inclined side 73A obliquely disposed in a first direction and a second inclined side 73B obliquely disposed in a second direction different from the first direction. The first inclined side 73A and the second inclined side 73B may be continuously disposed via a corner portion 74A. The first inclined side 73A and the second inclined side 73B may be inclined in a direction approaching the fourth upright wall portion 22D as a distance from the corner portion 74A increases.

For example, as illustrated in FIG. 7, in the case where the electronic device 10 is disposed with the fourth upright wall portion 22D downward, the first inclined side 73A and the second inclined side 73B are disposed above the contact portion 63 so as to cover the contact portion 63.

As illustrated in FIG. 7, at least one of the long sides 71 of the continuous protruding portions 70 may include a third inclined side 73C obliquely disposed in a third direction and a fourth inclined side 73D obliquely disposed in a fourth direction different from the third direction. The third inclined side 73C and the fourth inclined side 73D may be continuously disposed via a corner portion 74B. The third inclined side 73C and the fourth inclined side 73D may be inclined in a direction approaching the fourth upright wall portion 22D as a distance from the corner portion 74B increases.

For example, as illustrated in FIG. 7, in the case where the electronic device 10 is disposed with the fourth upright wall portion 22D downward, the third inclined side 73C and the fourth inclined side 73D are disposed above the contact portion 63 so as to cover the contact portion 63. The third inclined side 73C and the fourth inclined side 73D may be disposed at positions below the first inclined side 73A and the second inclined side 73B and above the contact portion 63.

Inclination angles of the first inclined side 73A and the third inclined side 73C may be the same (not illustrated) or may be different from each other (see FIG. 7). The inclination angle of the third inclined side 73C may be larger than the inclination angle of the first inclined side 73A.

Inclination angles of the second inclined side 73B and the fourth inclined side 73D may be the same (not illustrated) or different from each other (see FIG. 7). The inclination angle of the fourth inclined side 73D may be larger than the inclination angle of the second inclined side 73B.

At least one of the first inclined side 73A, the second inclined side 73B, the third inclined side 73C, and the fourth inclined side 73D may be inclined in a straight line (see FIG. 7) or may be inclined in a curved line (not illustrated).

FIG. 7 illustrates an example in which the lid portion 60 has two long sides 71, that is, a set of the first inclined side 73A and the second inclined side 73B and a set of the third inclined side 73C and the fourth inclined side 73D, but the number of long sides 71 may be one, three or more.

Next, as illustrated in FIG. 7, operation and effects of the first inclined side 73A, the second inclined side 73B, the third inclined side 73C, and the fourth inclined side 73D in the case where the electronic device 10 is disposed with the fourth upright wall portion 22D downward will be described.

For example, when a water droplet enters from a second gap 91B between the second upright wall portion 22B and the lid portion 60, the water droplet moves downward along the inner surface 61 of the lid portion 60. However, the water droplet hits the first inclined side 73A or the second inclined side 73B and moves along the inclination of the first inclined side 73A or the second inclined side 73B (see a water droplet path 103A). Further, even if a part of the water droplet hitting the first inclined side 73A or the second inclined side 73B moves downward without following the inclination of the first inclined side 73A or the second inclined side 73B, the water droplet hits the third inclined side 73C or the fourth inclined side 73D and moves along the inclination of the third inclined side 73C or the fourth inclined side 73D (see a water droplet path 103B).

As described above, by providing the first inclined side 73A and the second inclined side 73B (and the third inclined side 73C and the fourth inclined side 73D) as illustrated in FIG. 7, it is possible to prevent the water droplet entering from the second gap 91B from reaching the contact portion 63. That is, it is possible to prevent the water droplet entering from the second gap 91B from reaching the circuit board 31 through the contact portion 63.

The first inclined side 73A and the second inclined side 73B (and the third inclined side 73C and the fourth inclined side 73D) illustrated in FIG. 7 may be disposed so as to cover the contact portion 63 on positions above the contact portion 63 in the case where the electronic device 10 is disposed with the first upright wall portion 22A (or the third upright wall portion 22C) downward.

In the present embodiment, the lid portion 60 is provided with the first long side 72A, the second long side 72B, the third long side 72C, the fourth long side 72D, the first inclined side 73A, the second inclined side 73B, the third inclined side 73C, and the fourth inclined side 73D as the continuous protruding portion 70, but in a case where an installation direction of the electronic device 10 in the vehicle compartment (that is, which of the electronic device 10 is disposed downward) is determined in advance, the continuous protruding portion 70 may be provided only above the contact portion 63 of the lid portion 60.

As illustrated in FIGS. 4, 5, 6, and 7, the lid portion 60, the circuit board 31, and the case body 20 may be fastened by the screws 82 at four corners. Further, the lid portion 60 may include contact portions 83 configured to be in contact with the circuit board 31, and protruding portions 84 corresponding to the contact portions 83, which are provided on a part of the inner surface 61, around the screws 82. Each of the protruding portions 84 may protrude toward the bottom surface 21 of the case body 20. In this case, similarly to the continuous protruding portion 70 described above, the lid portion 60 may include a continuous protruding portion (not illustrated) disposed so as to prevent a water droplet entering from the gap of the lid portion 60 from reaching the circuit board 31 via the protruding portion 84 and the contact portion 83. For example, the continuous protruding portion may be disposed so as to surround the contact portion 83 and the protruding portion 84. Accordingly, similarly to the continuous protruding portion 70 described above, it is possible to move the water droplet entering from the gap of the lid portion 60 along the inclination of the continuous protruding portion, and it is possible to prevent the entering water droplet from reaching the circuit board 31 via the protruding portion 84 and the contact portion 83.

(Summary of Present Disclosure)

The following technique is disclosed from the above description of the embodiment.

<Technique 1>

The electronic device 10 according to the present disclosure includes the case body 20, the circuit board 31, and the lid portion 60. The case body 20 includes at least the bottom surface 21, the first upright wall portion 22A, the second upright wall portion 22B, the third upright wall portion 22C, and the fourth upright wall portion 22D disposed around the bottom surface 21. The electronic components 32 are mounted on the circuit board 31, and the circuit board 31 is accommodated in the case body 20. The lid portion 60 is disposed to correspond to at least a part of the first top portion 23A of the first upright wall portion 22A, the second top portion 23B of the second upright wall portion 22B, the third top portion 23C of the third upright wall portion 22C, and the fourth top portion 23D of the fourth upright wall portion 22D, covers the circuit board 31, and has the inner surface 61 facing the bottom surface 21, and the outer surface 62 opposite to the inner surface 61. The lid portion 60 includes the contact portion 63 provided on a part of the inner surface 61 and configured to be in contact with the circuit board 31. The lid portion 60 includes the continuous protruding portions 70 that are continuous with a predetermined length along the inner surface 61 and protrude toward the bottom surface 21. In the case where the electronic device 10 is disposed with the first upright wall portion 22A downward, at least one of the long sides 71 of the continuous protruding portion 70 on the inner surface 61 is disposed above the contact portion 63 so as to cover the contact portion 63.

According to this configuration, when a water droplet adhering to the inner surface 61 of the lid portion 60 moves downward, the water droplet hits the continuous protruding portion 70 and does not reach the contact portion 63, it is possible to prevent the water droplet from reaching the circuit board 31 through the contact portion 63.

<Technique 2>

In the electronic device 10 according to Technique 1, the lid portion 60 and the circuit board 31 are fastened to each other at the contact portion 63.

<Technique 3>

In the electronic device 10 according to Technique 1 or 2, the lid portion 60 includes the protruding portion 64 corresponding to the contact portion 63.

<Technique 4>

In the electronic device 10 according to any one of Techniques 1 to 3, the lid portion 60 and the circuit board 31 are fastened to each other by the screw 81 at the contact portion 63.

<Technique 5>

In the electronic device 10 according to any one of Techniques 1 to 4, in the case where the electronic device 10 is disposed with the first upright wall portion 22A downward, at least one of the long sides 71 of the continuous protruding portion 70 on the inner surface 61 is obliquely disposed above the contact portion 63 and covers the contact portion 63.

<Technique 6>

In the electronic device 10 according to any one of Techniques 1 to 5, the long side 71 of the continuous protruding portion 70 on the inner surface 61 is set as the first long side 72A, and the continuous protruding portion 70 on the inner surface 61 further includes the second long side 72B along the first long side 72A.

<Technique 7>

In the electronic device 10 according to any one of Techniques 1 to 6, in the case where the electronic device 10 is disposed with the fourth upright wall portion 22D downward, at least one of the long sides 71 of the continuous protruding portion 70 on the inner surface 61 includes the first inclined side 73A obliquely disposed in a first direction and the second inclined side 73B obliquely disposed in a second direction different from the first direction.

<Technique 8>

In the electronic device 10 according to Technique 7, the first inclined side 73A and the second inclined side 73B are continuously disposed via the corner portion 74A.

<Technique 9>

In the electronic device 10 according to any one of Techniques 1 to 8, the lid portion 60 is made of metal.

<Technique 10>

In the electronic device 10 according to Technique 9, the continuous protruding portion 70 is formed on the lid portion 60 made of metal by press working.

Although the embodiment has been described above with reference to the accompanying drawings, the present disclosure is not limited to such an embodiment. It is apparent to those skilled in the art that various changes, modifications, substitutions, addition, deletions, and equivalents can be conceived within the scope described in the claims, and it is understood that the scope of the present disclosure includes these. In addition, constituent elements in the embodiment described above may be freely combined without departing from the gist of the invention.

### INDUSTRIAL APPLICABILITY

The technique of the present disclosure is useful for an electronic device that is required to have a drip-proof performance.

What is claimed is:

1. An electronic device comprising:
a case body including at least a bottom surface, a first upright wall portion, a second upright wall portion, a third upright wall portion, and a fourth upright wall portion disposed around the bottom surface;
a circuit board on which an electronic component is mounted and which is accommodated in the case body; and
a lid portion disposed so as to correspond to at least a part of a first top portion of the first upright wall portion, a second top portion of the second upright wall portion, a third top portion of the third upright wall portion, and a fourth top portion of the fourth upright wall portion, covering the circuit board, and having an inner surface facing the bottom surface and an outer surface opposite to the inner surface,
wherein the lid portion includes a contact portion provided on a part of the inner surface and configured to be in contact with the circuit board,
wherein the lid portion includes a continuous protruding portion that is continuous with a predetermined length along the inner surface and protrudes toward the bottom surface, and
wherein in a case where the electronic device is disposed with the first upright wall portion downward, at least one of long sides of the continuous protruding portion on the inner surface is disposed above the contact portion so as to cover the contact portion.

2. The electronic device according to claim 1,
wherein the lid portion and the circuit board are fastened to each other at the contact portion.

3. The electronic device according to claim 2,
wherein the lid portion includes a protruding portion corresponding to the contact portion.

4. The electronic device according to claim 3,
wherein the lid portion and the circuit board are fastened by a screw at the contact portion.

5. The electronic device according to claim 1,
wherein in the case where the electronic device is disposed with the first upright wall portion downward, at least one of the long sides of the continuous protruding portion on the inner surface is obliquely disposed above the contact portion and covers the contact portion.

6. The electronic device according to claim 1,
wherein the long side of the continuous protruding portion on the inner surface is set as a first long side, and
wherein the continuous protruding portion on the inner surface further includes a second long side along the first long side.

7. The electronic device according to claim 1,
wherein in a case where the electronic device is disposed with the fourth upright wall portion downward, at least one of the long sides of the continuous protruding portion on the inner surface includes a first inclined side obliquely disposed in a first direction and a second inclined side obliquely disposed in a second direction different from the first direction.

8. The electronic device according to claim 7,
wherein the first inclined side and the second inclined side are continuously disposed via a corner portion.

9. The electronic device according to claim 1,
wherein the lid portion is made of metal.

10. The electronic device according to claim 9,
wherein the continuous protruding portion is formed on the lid portion made of metal by press working.
